(19) United States
(12) Patent Application Publication
(10) Pub. No.: US 2024/0284743 A1
(43) Pub. Date: Aug. 22, 2024

(54) PIXEL LAYOUT STRUCTURE, DISPLAY PANEL, MASK PLATE ASSEMBLY

(71) Applicant: HKC CORPORATION LIMITED, Shenzhen (CN)

(72) Inventors: YANGLING TANG, Shenzhen (CN); XIUFENG ZHOU, Shenzhen (CN); XIN YUAN, Shenzhen (CN); RONGRONG LI, Shenzhen (CN)

(21) Appl. No.: 18/213,837

(22) Filed: Jun. 24, 2023

(30) Foreign Application Priority Data
Feb. 22, 2023 (CN) 202310151887.3

(51) Int. Cl. H10K 59/35

(52) U.S. Cl. CPC H10K 59/353; H10K 59/352

(57) ABSTRACT

Disclosed are a pixel layout structure, a display panel, a mask plate assembly. The pixel layout structure includes multiple repeating units arranged in an array. An outer contour of each repeating unit is a rectangle; each repeating unit includes four pixel units, and each pixel unit comprises a first sub-pixel, a second sub-pixel, and a third sub-pixel; the four first sub-pixels are arranged around a center of the repeating unit; an outer contour of the four first sub-pixels includes a first edge, a second edge, a third edge, and a fourth edge; each of the first edge and the third edge is arranged with two second sub-pixels, and each of the second edge and the fourth edge is arranged with two third sub-pixels; or each of the first edge, the second edge, the third edge, and the fourth edge is arranged with a second sub-pixel and a third sub-pixel.

### CROSS REFERENCE

The present application claims priority of China Patent Application No. 202310151887.3 filed on Feb. 22, 2023, the entire contents of which are hereby incorporated by reference.

### TECHNICAL FIELD

The present disclosure relates to the field of display technologies, and in particular to a pixel layout structure, a display panel, a mask plate assembly.

### BACKGROUND

A mask plate is usually applied to form a pixel structure by vapor deposition process. The mask plate has a limitation of minimum aperture, and the spacing between the apertures must be ensured to be greater than a certain value. Therefore, the pixel opening ratio is limited.

Currently, pixels per inch (PPI) of a display panel is becoming more and more demanding, and the pixel opening ratio of the display panel is limited by the aperture of the mask plate and the precision of the vapor deposition process, which brings difficulty to achieve high PPI.

### SUMMARY OF THE DISCLOSURE

The present disclosure provides a pixel layout structure, a display panel, a mask plate assembly, to reduce the difficulty of the mask plate hole-opening process while increasing the pixel opening ratio.

To solve the above technical problem, the present disclosure proposes a first technical solution: a pixel layout structure, including: a plurality of repeating units arranged in an array; wherein an outer contour of each repeating unit is a rectangle; each repeating unit includes four pixel units, and each pixel unit includes a first sub-pixel, a second sub-pixel, and a third sub-pixel that are adjacent to each other; an outer contour of each pixel unit is a rectangle; a shape of each of the first sub-pixel, the second sub-pixel, and the third sub-pixel is a polygon; the four first sub-pixels are arranged around a center of the repeating unit; an outer contour of the four first sub-pixels includes a first edge, a second edge, a third edge, and a fourth edge, the first edge being disposed opposite to the third edge and the second edge being disposed opposite to the fourth edge; wherein each of the first edge and the third edge is arranged with two corresponding second sub-pixels, and each of the second edge and the fourth edge is arranged with two corresponding third sub-pixels; or each of the first edge, the second edge, the third edge, and the fourth edge is arranged with a corresponding second sub-pixel and a corresponding third sub-pixel.

To solve the above technical problem, the present disclosure proposes a second technical solution: a display panel, including the pixel layout structure as described.

To solve the above technical problem, the present disclosure proposes a third technical solution: A mask plate assembly, configured to prepare the pixel layout structure as described and including: a first mask plate, configured to vaporize the first sub-pixel; wherein the first mask plate defines a plurality of first apertures, and the four first sub-pixels of the repeating unit share a corresponding first aperture; a second mask plate, configured to vaporize the second sub-pixel; wherein the second mask plate defines a plurality of second apertures; for any two adjacent repeating units, the second sub-pixels that are adjacent to each other on the two adjacent repeating units share a corresponding second aperture; and a third mask plate, configured to vaporize the third sub-pixel; wherein the third mask plate defines a plurality of third apertures; for any two adjacent repeating units, the third sub-pixels that are adjacent to each other on the two adjacent repeating units share a corresponding third aperture.

### BRIEF DESCRIPTION OF THE DRAWINGS

In order to illustrate the technical solutions more clearly in the embodiments of the present disclosure, the following will briefly describe the accompanying drawings required in the description of the embodiments, and it is obvious that the following description of the accompanying drawings are only some of the embodiments of the present disclosure. For those skilled in the art, other accompanying drawings may be obtained from these drawings without creative labor.

FIG. 1 is a schematic view of a pixel layout structure in the related art.

FIG. 2 is a structural schematic view of a pixel layout structure according to a first embodiment of the present disclosure.

FIG. 3 is a structural schematic view of a first mask plate for preparing the pixel layout structure shown in FIG. 2.

FIG. 4 is a structural schematic view of a second mask plate for preparing the pixel layout structure shown in FIG. 2.

FIG. 5 is a structural schematic view of a third mask plate for preparing the pixel layout structure shown in FIG. 2.

FIG. 6 is a structural schematic view of a pixel layout structure according to a second embodiment of the present disclosure.

FIG. 7 is an enlarged structural schematic view of a second sub-pixel shown in FIG. 6.

FIG. 8 is a structural schematic view of a second mask plate for preparing the pixel layout structure shown in FIG. 6.

FIG. 9 is a structural schematic view of a third mask plate for preparing the pixel layout structure shown in FIG. 6.

FIG. 10 is a structural schematic view of a pixel layout structure according to a third embodiment of the present disclosure.

FIG. 11 is a structural schematic view of a first mask plate for preparing the pixel layout structure shown in FIG. 10.

FIG. 12 is a structural schematic view of a second mask plate for preparing the pixel layout structure shown in FIG. 10.

FIG. 13 is a structural schematic view of a third mask plate for preparing the pixel layout structure shown in FIG. 10.

FIG. 14 is a structural schematic view of a pixel layout structure according to a fourth embodiment of the present disclosure.

FIG. 15 is a structural schematic view of a first mask plate for preparing the pixel layout structure shown in FIG. 14.

FIG. 16 is a structural schematic view of a second mask plate for preparing the pixel layout structure shown in FIG. 14.

FIG. 17 is a structural schematic view of a third mask plate for preparing the pixel layout structure shown in FIG. 14.

FIG. 18 is a structural schematic view of a pixel layout structure according to a fifth embodiment of the present disclosure.

FIG. 19 is a structural schematic view of a first mask plate for preparing the pixel layout structure shown in FIG. 18.

FIG. 20 is a structural schematic view of a second mask plate for preparing the pixel layout structure shown in FIG. 18.

FIG. 21 is a structural schematic view of a third mask plate for preparing the pixel layout structure shown in FIG. 18.

### DETAILED DESCRIPTION

The following will be a clear and complete description of the technical solutions in the embodiments of the present disclosure, in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without making creative labor fall within the scope of the present disclosure.

In the following description, specific details such as particular system structures, interfaces, techniques, and the like are presented for the purpose of illustration and not for limitation, in order to provide a thorough understanding of the present disclosure.

The terms “first”, “second” and “third” in the present disclosure are used for descriptive purposes only and are not to be construed as indicating or implying relative importance or implicitly specifying the number of indicated technical features. Thus, features defined with “first”, “second”, “third” may explicitly or implicitly include at least one of the described features. In the description of the present disclosure, “plurality” means at least two, e.g., two, three, etc., unless otherwise expressly and specifically limited. Directional indications (such as up, down, left, right, forward, backward . . . ) in the present disclosure, the directional indications are intended only to explain the relative positions, movements, etc. of components in a particular posture (as shown in the accompanying drawings), and if that particular posture is changed, the directional indications are also changed accordingly. The terms “including”, “comprising”, or any other variation thereof are intended to cover non-exclusive inclusion. For example, a process, method, system, product, or apparatus that includes a series of steps or units is not limited to the listed steps or units, but optionally further includes steps or units that are not listed, or optionally further includes other steps or components that are inherent to the process, method, product, or apparatus.

References herein to “embodiments” mean that particular features, structures, or characteristics described in connection with the embodiments may be included in at least one embodiment of the present disclosure. The presence of the phrase at each location in the specification does not necessarily mean the same embodiment, nor is it a separate or alternative embodiment that is mutually exclusive with other embodiments. It is understood, both explicitly and implicitly, by those skilled in the art that the embodiments described herein may be combined with other embodiments.

The present disclosure is described in detail below in conjunction with the accompanying drawings and embodiments.

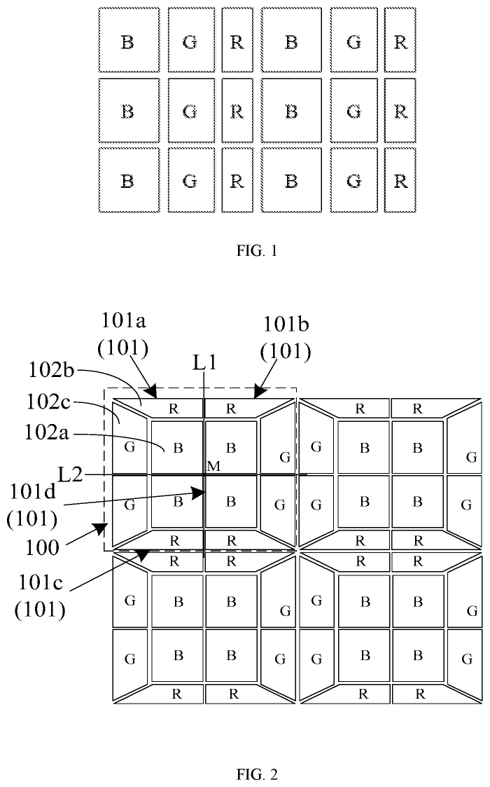

Referring to FIG. 1, FIG. 1 is a schematic view of a pixel layout structure in the related art.

In the related art, the pixel layout is often adopted with a cyclic arrangement of blue sub-pixels (B), green sub-pixels (G), and red sub-pixels (R). When vaporizing the pixel structure using a mask plate, each sub-pixel corresponds to a mask plate aperture. Limited by the spacing between mask plate apertures, a certain distance must exist between sub-pixels, such that the pixel opening ratio is limited.

The pixel opening ratio of the display panel is limited by the opening of the mask plate and the precision of the evaporation process, which makes it difficult to achieve high PPI and cannot meet the requirements of the display market for higher PPI and longer lifetime.

In view of this, the present disclosure provides a novel pixel layout structure, a display panel adopted with the pixel layout structure, and a mask plate assembly for preparing the pixel layout structure, to achieve higher PPI and longer lifetime, while reducing the difficulty of the mask plate hole-opening process.

Referring to FIG. 2, FIG. 2 is a structural schematic view of a pixel layout structure according to a first embodiment of the present disclosure.

The pixel layout structure includes multiple repeating units 100 arranged in an array.

An outer contour of each repeating unit 100 is rectangular; in some embodiments, a length dimension of the outer contour of the repeating unit 100 is greater than a width dimension of the outer contour of the repeating unit 100.

Each repeating unit 100 includes four pixel units 101; namely, a first pixel unit 101a, a second pixel unit 101b, a third pixel unit 101c, and a fourth pixel unit 101d. An outer contour of each pixel unit 101 is rectangular; in some embodiments, a length dimension of the outer contour of the pixel unit 101 is greater than a width dimension of the outer contour of the pixel unit 101. Each pixel unit 101 includes a first sub-pixel 102a, a second sub-pixel 102b, and a third sub-pixel 102c that are adjacent to each other. A shape of each of the first sub-pixel 102a, the second sub-pixel 102b, and the third sub-pixel 102c is a polygon. Colors of the first sub-pixel 102a, the second sub-pixel 102b, and the third sub-pixel 102c are red, green, and blue; exemplarily, the color of the first sub-pixel 102a is blue, the color of the second sub-pixel 102b is red, and the color of the third sub-pixel 102c is green (as shown in FIG. 2).

It can be understood that since each repeating unit 100 includes four pixel units 101, and each pixel unit 101 includes a first sub-pixel 102a, a second sub-pixel 102b, and a third sub-pixel 102c. That is, each repeating unit 100 includes four first sub-pixels 102a, four second sub-pixels 102b, and four third sub-pixels 102c.

The four first sub-pixels 102a are arranged around a center M of the repeating unit 100. The outer contour of the four first sub-pixels 102a forms a rectangle. The four first sub-pixels 102a are arranged adjacent to each other and in a rectangular shape. The outer contour of the four first sub-pixels 102a includes a first edge, a second edge, a third edge, and a fourth edge, the first edge being disposed opposite to the third edge and the second edge being disposed opposite to the fourth edge. Each of the first edge and the third edge is arranged with two corresponding second sub-pixels 102b, and each of the second edge and the fourth edge is arranged with two corresponding third sub-pixels 102c.

Each repeating unit 100 has a first symmetry axis L1 and a second symmetry axis L2. The first symmetry axis L1 and the second symmetry axis L2 are perpendicular to each other. An intersection of the first symmetry axis L1 and the second symmetry axis L2 is the center M of the repeating unit 100. The first pixel unit 101a and the second pixel unit 101b are arranged symmetrically along the first symmetry axis L1, the third pixel unit 101c and the fourth pixel unit 101d are arranged symmetrically along the first symmetry axis L1, the first pixel unit 101a and the third pixel unit 101c are arranged symmetrically along the second symmetry axis L2, and the second pixel unit 101b and the fourth pixel unit 101d are arranged symmetrically along the second symmetry axis L2.

Any two adjacent repeating units 100 are arranged axially symmetrical. For any two adjacent repeating units 100 (repeating unit A and repeating unit B), a side of the repeating unit A faces a side of the repeating unit B, sub-pixels on the side of the repeating unit A and the side of the repeating unit B are in same colors, to facilitate the shared opening of the mask plate which will be described in detail in the subsequent content introduction.

In some embodiments, as shown in FIG. 2, the first sub-pixel 102a has a rectangular shape, the second sub-pixel 102b has a right-angle trapezoid shape, and the third sub-pixel 102c has a right-angle trapezoid shape.

In some embodiments, as shown in FIG. 2, the area of the first sub-pixel 102a is greater than the area of the second sub-pixel 102b, and the area of the first sub-pixel 102a is greater than the area of the third sub-pixel 102c.

It should be noted that the present disclosure does not limit the proportional relationship between the area sizes of the first sub-pixel 102a, the second sub-pixel 102b, and the third sub-pixel 102c and color thereof, and the area size and color of the first sub-pixel 102a, the second sub-pixel 102b, and the third sub-pixel 102c are designed specifically according to luminous requirements.

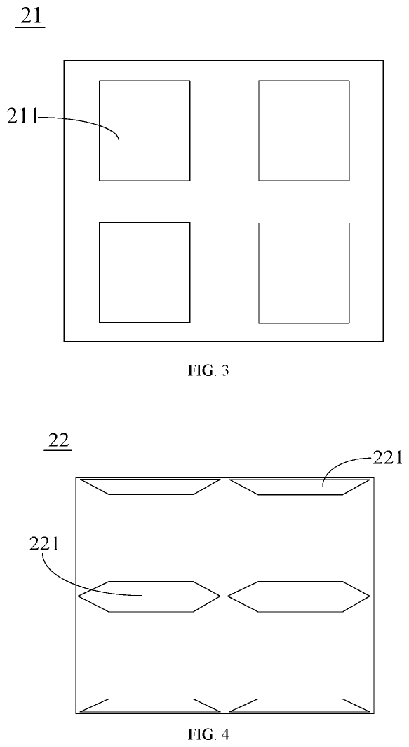

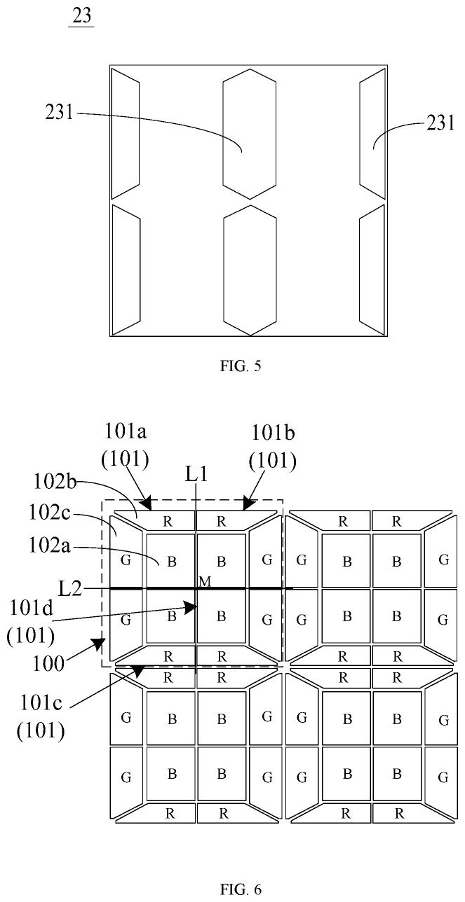

Referring to FIGS. 3-5, FIG. 3 is a structural schematic view of a first mask plate for preparing the pixel layout structure shown in FIG. 2, FIG. 4 is a structural schematic view of a second mask plate for preparing the pixel layout structure shown in FIG. 2, FIG. 5 is a structural schematic view of a third mask plate for preparing the pixel layout structure shown in FIG. 2.

The present disclosure further provides a mask plate assembly for preparing the above pixel layout structure, the mask plate assembly including a first mask plate 21, a second mask plate 22, and a third mask plate 23.

The first mask plate 21 is configured to vaporize the first sub-pixel 102a; the first mask plate 21 defines multiple first apertures 211, and four first sub-pixels 102a of each repeating unit 100 share a first aperture 211 (as shown in FIG. 3).

The second mask plate 22 is configured to vaporize the second sub-pixel 102b; the second mask plate 22 defines multiple second apertures 221. For any two adjacent repeating units 100 (repeating unit A and repeating unit B), a side of the repeating unit A faces a side of the repeating unit B, and the four second sub-pixels 102b, on the side of the repeating unit A and the side of the repeating unit B, share a second aperture 221. The two second sub-pixels 102b on each side of the repeating unit 100 share a second aperture 221 (as shown in FIG. 4).

The third mask plate 23 is configured to vaporize the third sub-pixel 102c; the third mask plate 23 defines multiple third apertures 231. For any two adjacent repeating units 100 (repeating unit A and repeating unit B), a side of the repeating unit A faces a side of the repeating unit B, and the four third sub-pixels 102c, on the side of the repeating unit A and the side of the repeating unit B, share a third aperture 231. The two third sub-pixels 102c on each side of the repeating unit 100 share a third aperture 231 (as shown in FIG. 5).

By the above design of the pixel layout structure, the present disclosure makes the sub-pixels with the same color adjacent to each other share one mask plate aperture, which increases the distance between mask plate apertures, reduces the process difficulty of mask plate hole-opening, and reduces the distance between adjacent sub-pixels, thereby increasing the pixel opening ratio, improving the pixel PPI, and extending the pixel lifetime. For example, the four first sub-pixels 102a share one first aperture 211, increasing the distance between adjacent first apertures 211; the spacing between adjacent first sub-pixels 102a is not limited by the spacing between first apertures 211 of the first mask plate 21, thereby reducing the distance between four adjacent first sub-pixels 102a.

In addition, by setting the shapes of the first sub-pixel 102a, the second sub-pixel 102b, and the third sub-pixel 102c as polygons, each pixel unit 101 has a rectangular outer contour, such that the first aperture 211 corresponding to the multiple first sub-pixels 102a, the second aperture 221 corresponding to the multiple second sub-pixels 102b, and the third aperture 231 corresponding to the multiple third sub-pixels 102c are polygons in shape that are easy to process, further reducing the process difficulty of mask plate hole-opening.

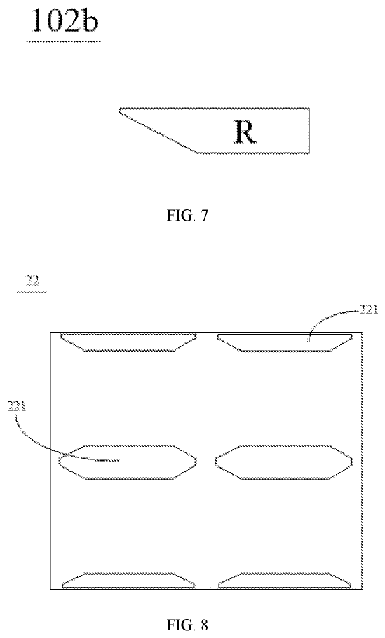

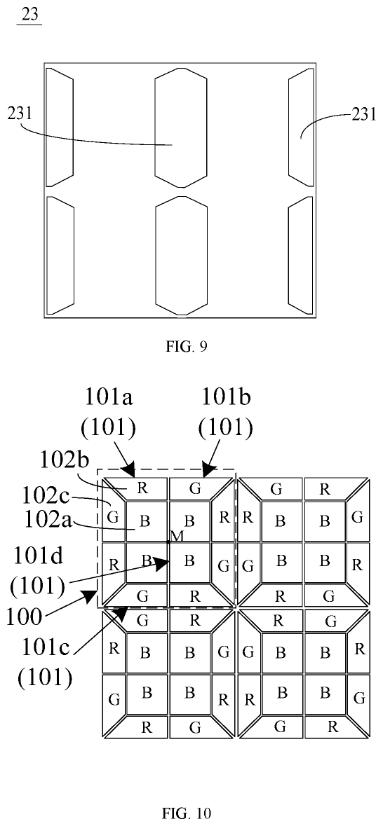

Referring to FIGS. 6-9, FIG. 6 is a structural schematic view of a pixel layout structure according to a second embodiment of the present disclosure, FIG. 7 is an enlarged structural schematic view of a second sub-pixel shown in FIG. 6, FIG. 8 is a structural schematic view of a second mask plate for preparing the pixel layout structure shown in FIG. 6, and FIG. 9 is a structural schematic view of a third mask plate for preparing the pixel layout structure shown in FIG. 6.

The arrangement of the second embodiment of the pixel layout structure is basically the same as that of the first embodiment of the pixel layout structure, with the difference that in the second embodiment of the pixel layout structure, the second sub-pixel 102b and the third sub-pixel 102c are corner-cut. The same part is not repeated.

Specifically, the second sub-pixel 102b and the third sub-pixel 102c are shaped as right-angled trapezoids, and an acute corner of each right-angled trapezoid is corner-cut. By tangenting the acute corner of the right-angle trapezoid, the shape of an outer contour formed by the mutually adjacent second sub-pixels 102b or the shape of an outer contour formed by the mutually adjacent third sub-pixels 102c in any adjacent repeating unit 100 does not have acute corners, and therefore the shape of the second aperture 221 shared by the mutually adjacent second sub-pixels 102b does not have acute corners (as shown in FIG. 8) or the shape of the third aperture 231 shared by the mutually adjacent third sub-pixels 102c does not have acute corners (as shown in FIG. 9), thereby facilitating the processing of the second aperture 221 or the third aperture 231 and reducing the difficulty of hole-opening the second mask plate 22 or the third mask plate 23.

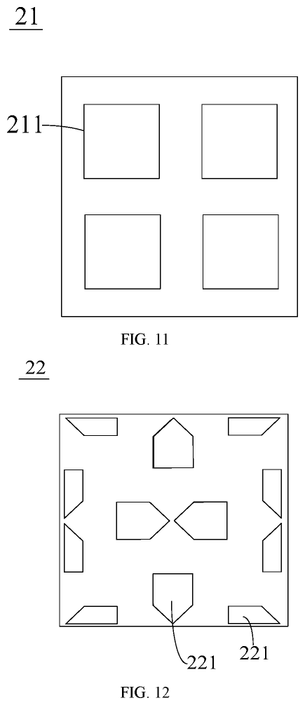

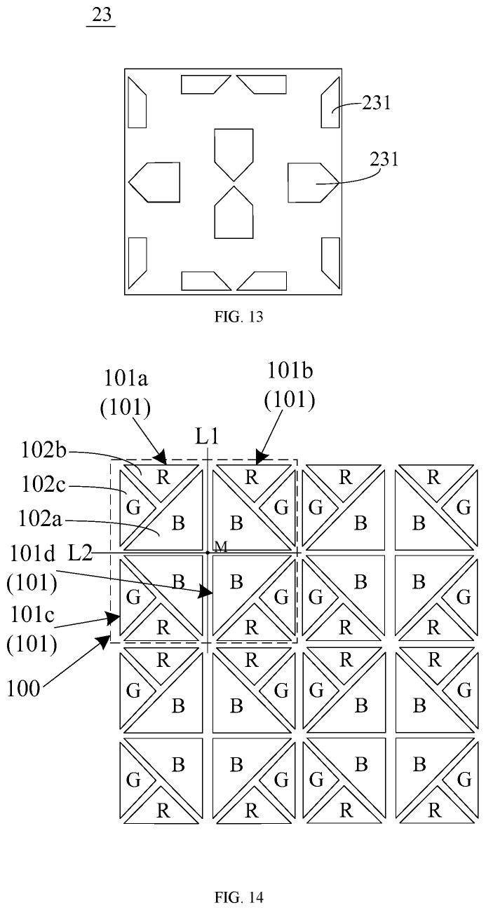

Referring to FIGS. 10-13, FIG. 10 is a structural schematic view of a pixel layout structure according to a third embodiment of the present disclosure, FIG. 11 is a structural schematic view of a first mask plate for preparing the pixel layout structure shown in FIG. 10, FIG. 12 is a structural schematic view of a second mask plate for preparing the pixel layout structure shown in FIG. 10, and FIG. 13 is a structural schematic view of a third mask plate for preparing the pixel layout structure shown in FIG. 10.

The arrangement of the third embodiment of the pixel layout structure differs from the arrangement of the first embodiment of the pixel layout structure in the relative position relationship between the second sub-pixel 102b, the third sub-pixel 102c, and the first sub-pixel 102a; and the relative position relationship between the first pixel unit 101a, the second pixel unit 101b, the third pixel unit 101c, and the fourth pixel unit 101d.

In the third embodiment of the pixel layout structure, the pixel layout structure includes multiple repeating units 100 arranged in an array, with any two adjacent repeating units 100 arranged in an axisymmetric manner. The outer contour of each repeating unit 100 is a rectangle; in some embodiments, the length dimension of the outer contour of the repeating unit 100 is equal to the width dimension, i.e., the outer contour of the repeating unit 100 is a square (which is a special rectangle). Each repeating unit 100 includes four pixel units 101, namely, a first pixel unit 101a, a second pixel unit 101b, a third pixel unit 101c, and a fourth pixel unit 101d. The second pixel unit 101b is formed by rotating the first pixel unit 101a 90 degrees clockwise around a center M of the repeating unit 100, and the fourth pixel unit 101d is formed by rotating the first pixel unit 101a 180 degrees clockwise around the center M of the repeating unit 100, and the third pixel unit 101c is formed by rotating the first pixel unit 101a 270 degrees clockwise around the center M of the repeating unit 100.

The outer contour of each pixel unit 101 is a rectangle; in some embodiments, the length dimension of the outer contour of the pixel unit 101 is equal to the width dimension, i.e., the outer contour of the pixel unit 101 is a square (which is a special rectangle). Each pixel unit 101 includes a first sub-pixel 102a, a second sub-pixel 102b, and a third sub-pixel 102c that are adjacent to each other. The shape of each of the first sub-pixel 102a, the second sub-pixel 102b, and the third sub-pixel 102c is a polygon. The colors of the first sub-pixel 102a, the second sub-pixel 102b, and the third sub-pixel 102c are red, green, and blue; exemplarily, the color of the first sub-pixel 102a is blue, the color of the second sub-pixel 102b is red, and the color of the third sub-pixel 102c is green (as shown in FIG. 10).

Since each repeating unit 100 includes four pixel units 101, and each pixel unit 101 includes a first sub-pixel 102a, a second sub-pixel 102b, and a third sub-pixel 102c, each repeating unit 100 includes four first sub-pixels 102a, four second sub-pixels 102b, and four third sub-pixels 102c. The four first sub-pixels 102a are arranged around the center M of the repeating unit 100. The outer contour of the four first sub-pixels 102a forms a rectangle. The four first sub-pixels 102a are arranged adjacent to each other and arranged in a rectangular shape. The outer contour of the four first sub-pixels 102a includes a first edge, a second edge, a third edge, and a fourth edge, the first edge being disposed opposite to the third edge and the second edge being disposed opposite to the fourth edge. Each of the first edge, the second edge, the third edge, and the fourth edge is arranged with a corresponding second sub-pixel 102 and a corresponding third sub-pixel 102c.

In some embodiments, as shown in FIG. 10, the first sub-pixel 102a has a rectangular shape, the second sub-pixel 102b has a right-angle trapezoid shape, and the third sub-pixel 102c has a right-angle trapezoid shape. The area of the first sub-pixel 102a is greater than the area of the second sub-pixel 102b, and the area of the first sub-pixel 102a is greater than the area of the third sub-pixel 102c. In some embodiments, the area of the second sub-pixel 102b is equal to the area of the third sub-pixel 102c. It should be noted that the shapes of the second sub-pixel 102b and the third sub-pixel 102c may be corner-cut, i.e., the acute corner of the right-angled trapezoid may be corner-cut, as may be seen in the second embodiment of the pixel layout structure, which can achieve the same technical effect and will not be described again.

The four first sub-pixels 102a of each repeating unit 100 share a first aperture 211 of a first mask plate 21 (as shown in FIG. 11). For any two adjacent repeating units 100 (repeating unit A and repeating unit B), a side of the repeating unit A faces a side of the repeating unit B, the two second sub-pixels 102b on the side of the repeating unit A and the side of the repeating unit B share a second aperture 221 of a second mask plate 22 (as shown in FIG. 12). The two third sub-pixels 102c on the side of the repeating unit A and the side of the repeating unit B share a third aperture 231 of a third mask plate 23 (as shown in FIG. 13). By the above design of the pixel layout structure, the present disclosure makes the sub-pixels with the same color adjacent to each other share one mask plate aperture, which increases the distance between mask plate apertures, reduces the process difficulty of mask plate hole-opening, and reduces the distance between adjacent sub-pixels, thereby increasing the pixel opening ratio, improving the pixel PPI, and extending the pixel lifetime.

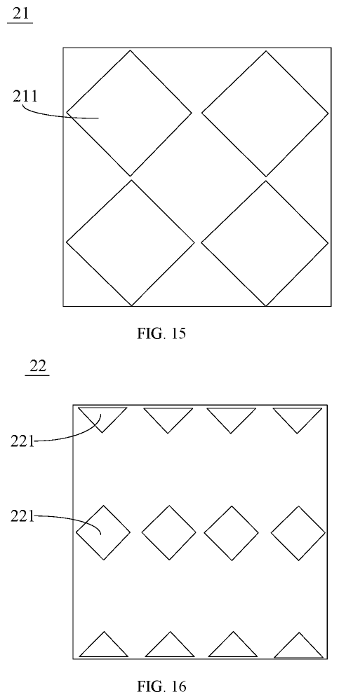

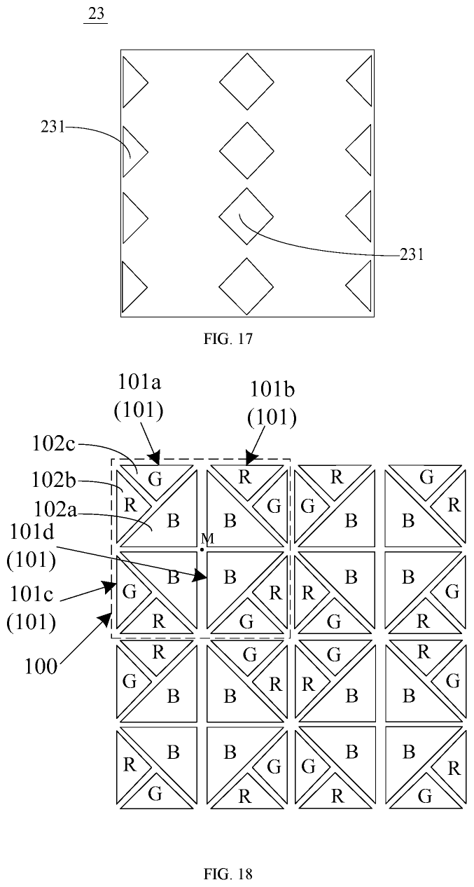

Referring to FIGS. 14-17, FIG. 14 is a structural schematic view of a pixel layout structure according to a fourth embodiment of the present disclosure, FIG. 15 is a structural schematic view of a first mask plate for preparing the pixel layout structure shown in FIG. 14, FIG. 16 is a structural schematic view of a second mask plate for preparing the pixel layout structure shown in FIG. 14, and FIG. 17 is a structural schematic view of a third mask plate for preparing the pixel layout structure shown in FIG. 14.

The arrangement of the fourth embodiment of the pixel layout structure differs from that of the first embodiment of the pixel layout structure in the shape of the first sub-pixel 102a, the second sub-pixel 102b, and the third sub-pixel 102c, and the relative position relationship between the second sub-pixel 102b, the third sub-pixel 102c, and the first sub-pixel 102a.

In the fourth embodiment of the pixel layout structure, the pixel layout structure includes multiple repeating units 100 arranged in an array, with any two adjacent repeating units 100 arranged in an axisymmetric manner. The outer contour of each repeating unit 100 is a rectangle; in some embodiments, the length dimension of the outer contour of the repeating unit 100 is equal to the width dimension, i.e., the outer contour of the repeating unit 100 is a square (which is a special rectangle). Each repeating unit 100 includes four pixel units 101, namely, a first pixel unit 101a, a second pixel unit 101b, a third pixel unit 101c, and a fourth pixel unit 101d. Each repeating unit 100 has a first symmetry axis L1 and a second symmetry axis L2. The first symmetry axis L1 and the second symmetry axis L2 are perpendicular to each other. An intersection of the first symmetry axis L1 and the second symmetry axis L2 is a center M of the repeating unit 100. The first pixel unit 101a and the second pixel unit 101b are arranged symmetrically along the first symmetry axis L1, the third pixel unit 101c and the fourth pixel unit 101d are arranged symmetrically along the first symmetry axis L1, the first pixel unit 101a and the third pixel unit 101c are arranged symmetrically along the second symmetry axis L2, and the second pixel unit 101b and the fourth pixel unit 101d are arranged symmetrically along the second symmetry axis L2.

The outer contour of each pixel unit 101 is a rectangle; in some embodiments, the length dimension of the outer contour of the pixel unit 101 is equal to the width dimension, i.e., the outer contour of the pixel unit 101 is a square (which is a special rectangle). Each pixel unit 101 includes a first sub-pixel 102a, a second sub-pixel 102b, and a third sub-pixel 102c that are adjacent to each other. The shape of each of the first sub-pixel 102a, the second sub-pixel 102b, and the third sub-pixel 102c is a polygon. The colors of the first sub-pixel 102a, the second sub-pixel 102b, and the third sub-pixel 102c are red, green, and blue; exemplarily, the color of the first sub-pixel 102a is blue, the color of the second sub-pixel 102b is red, and the color of the third sub-pixel 102c is green (as shown in FIG. 14).

Since each repeating unit 100 includes four pixel units 101, and each pixel unit 101 includes a first sub-pixel 102a, a second sub-pixel 102b, and a third sub-pixel 102c, each repeating unit 100 includes four first sub-pixels 102a, four second sub-pixels 102b, and four third sub-pixels 102c. The four first sub-pixels 102a are arranged around the center M of the repeating unit 100. The outer contour of the four first sub-pixels 102a forms a rhombus. The four first sub-pixels 102a are arranged adjacent to each other and arranged in a rectangular shape. The outer contour of the four first sub-pixels 102a includes a first edge, a second edge, a third edge, and a fourth edge, the first edge being disposed opposite to the third edge and the second edge being disposed opposite to the fourth edge. Each of the first edge, the second edge, the third edge, and the fourth edge is arranged with a corresponding second sub-pixel 102 and a corresponding third sub-pixel 102c.

In some embodiments, as shown in FIG. 14, the first sub-pixel 102a has a right triangle shape, the second sub-pixel 102b has a right triangle shape, and the third sub-pixel 102c has a right triangle shape. The area of the first sub-pixel 102a is greater than the area of the second sub-pixel 102b, and the area of the first sub-pixel 102a is greater than the area of the third sub-pixel 102c. In some embodiments, the area of the second sub-pixel 102b is equal to the area of the third sub-pixel 102c.

The four first sub-pixels 102a of each repeating unit 100 share a first aperture 211 of a first mask plate 21 (as shown in FIG. 15). For any two adjacent repeating units 100 (repeating unit A and repeating unit B), a side of the repeating unit A faces a side of the repeating unit B, the two second sub-pixels 102b on the side of the repeating unit A and the side of the repeating unit B share a second aperture 221 of a second mask plate 22 (as shown in FIG. 16). The two third sub-pixels 102c on the side of the repeating unit A and the side of the repeating unit B share a third aperture 231 of a third mask plate 23 (as shown in FIG. 17). By the above design of the pixel layout structure, the present disclosure makes the sub-pixels with the same color adjacent to each other share one mask plate aperture, which increases the distance between mask plate apertures, reduces the process difficulty of mask plate hole-opening, and reduces the distance between adjacent sub-pixels, thereby increasing the pixel opening ratio, improving the pixel PPI, and extending the pixel lifetime.

It is to be noted that the shapes of the second sub-pixel 102b and the third sub-pixel 102c may be corner-cut, i.e., at least one acute corner of the right triangle is corner-cut such that the shape of the second aperture 221 shared by the mutually adjacent second sub-pixels 102b does not have an acute corner or the shape of the third aperture 231 shared by the mutually adjacent third sub-pixels 102c does not have an acute corner, thereby facilitating the processing of the second aperture 221 or the third aperture 231 and reducing the difficulty of hole-opening the second mask plate 22 or the third mask plate 23, for which reference may be made to the second embodiment of the pixel layout structure to achieve a similar technical effect.

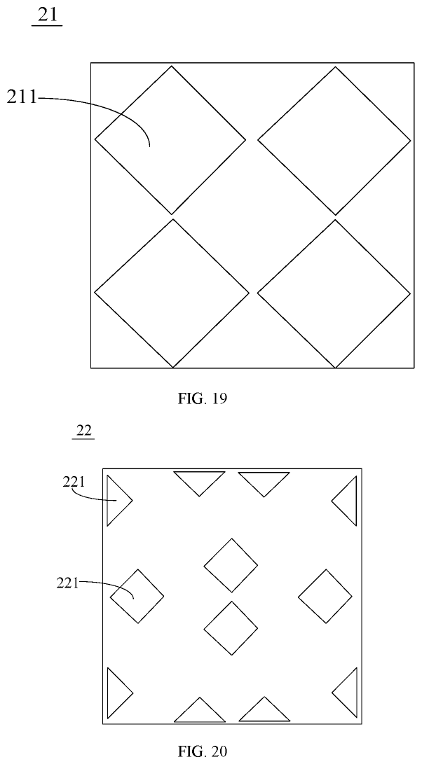

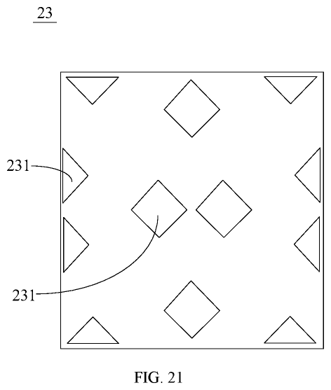

Referring to FIGS. 18-21, FIG. 18 is a structural schematic view of a pixel layout structure according to a fifth embodiment of the present disclosure, FIG. 19 is a structural schematic view of a first mask plate for preparing the pixel layout structure shown in FIG. 18, FIG. 20 is a structural schematic view of a second mask plate for preparing the pixel layout structure shown in FIG. 18, and FIG. 21 is a structural schematic view of a third mask plate for preparing the pixel layout structure shown in FIG. 18.

The arrangement of the fifth embodiment of the pixel layout structure differs from that of the first embodiment of the pixel layout structure in that the relative position relationship between the first pixel unit 101a, the second pixel unit 101b, the third pixel unit 101c, and the fourth pixel unit 101d; and the shapes of the first sub-pixel 102a, the second sub-pixel 102b, the third sub-pixel 102c; and the relative position relationship between the second sub-pixel 102b, the third sub-pixel 102c, and the first sub-pixel 102a.

In the fifth embodiment of the pixel layout structure, the pixel layout structure includes multiple repeating units 100 arranged in an array, with any two adjacent repeating units 100 arranged in an axisymmetric manner. The outer contour of each repeating unit 100 is a rectangle; in some embodiments, the length dimension of the outer contour of the repeating unit 100 is equal to the width dimension, i.e., the outer contour of the repeating unit 100 is a square (which is a special rectangle). Each repeating unit 100 includes four pixel units 101, namely, a first pixel unit 101a, a second pixel unit 101b, a third pixel unit 101c, and a fourth pixel unit 101d. The second pixel unit 101b is formed by rotating the first pixel unit 101a 90 degrees clockwise around a center M of the repeating unit 100, and the fourth pixel unit 101d is formed by rotating the first pixel unit 101a 180 degrees clockwise around the center M of the repeating unit 100, and the third pixel unit 101c is formed by rotating the first pixel unit 101a 270 degrees clockwise around the center M of the repeating unit 100.

The outer contour of each pixel unit 101 is a rectangle; in some embodiments, the length dimension of the outer contour of the pixel unit 101 is equal to the width dimension, i.e., the outer contour of the pixel unit 101 is a square (which is a special rectangle). Each pixel unit 101 includes a first sub-pixel 102a, a second sub-pixel 102b, and a third sub-pixel 102c that are adjacent to each other. The shape of each of the first sub-pixel 102a, the second sub-pixel 102b, and the third sub-pixel 102c is a polygon. The colors of the first sub-pixel 102a, the second sub-pixel 102b, and the third sub-pixel 102c are red, green, and blue; exemplarily, the color of the first sub-pixel 102a is blue, the color of the second sub-pixel 102b is red, and the color of the third sub-pixel 102c is green (as shown in FIG. 18).

Since each repeating unit 100 includes four pixel units 101, and each pixel unit 101 includes a first sub-pixel 102a, a second sub-pixel 102b, and a third sub-pixel 102c, each repeating unit 100 includes four first sub-pixels 102a, four second sub-pixels 102b, and four third sub-pixels 102c. The four first sub-pixels 102a are arranged around the center M of the repeating unit 100. The outer contour of the four first sub-pixels 102a is in a rhombus shape. The four first sub-pixels 102a are arranged adjacent to each other and arranged in a rectangular shape. The outer contour of the four first sub-pixels 102a includes a first edge, a second edge, a third edge, and a fourth edge, the first edge being disposed opposite to the third edge and the second edge being disposed opposite to the fourth edge. Each of the first edge, the second edge, the third edge, and the fourth edge is arranged with a corresponding second sub-pixel 102 and a corresponding third sub-pixel 102c.

In some embodiments, as shown in FIG. 18, the first sub-pixel 102a has a right triangle shape, the second sub-pixel 102b has a right triangle shape, and the third sub-pixel 102c has a right triangle shape. The area of the first sub-pixel 102a is greater than the area of the second sub-pixel 102b, and the area of the first sub-pixel 102a is greater than the area of the third sub-pixel 102c. In some embodiments, the area of the second sub-pixel 102b is equal to the area of the third sub-pixel 102c.

The four first sub-pixels 102a of each repeating unit 100 share a first aperture 211 of a first mask plate 21 (as shown in FIG. 19). For any two adjacent repeating units 100 (repeating unit A and repeating unit B), a side of the repeating unit A faces a side of the repeating unit B, the two second sub-pixels 102b on the side of the repeating unit A and the side of the repeating unit B share a second aperture 221 of a second mask plate 22 (as shown in FIG. 20). The two third sub-pixels 102c on the side of the repeating unit A and the side of the repeating unit B share a third aperture 231 of a third mask plate 23 (as shown in FIG. 21). By the above design of the pixel layout structure, the present disclosure makes the sub-pixels with the same color adjacent to each other share one mask plate aperture, which increases the distance between mask plate apertures, reduces the process difficulty of mask plate hole-opening, and reduces the distance between adjacent sub-pixels, thereby increasing the pixel opening ratio, improving the pixel PPI, and extending the pixel lifetime.

It is to be noted that the shapes of the second sub-pixel 102b and the third sub-pixel 102c may be corner-cut, i.e., at least one acute corner of the right triangle is corner-cut such that the shape of the second aperture 221 shared by the mutually adjacent second sub-pixels 102b does not have an acute corner or the shape of the third aperture 231 shared by the mutually adjacent third sub-pixels 102c does not have an acute corner, thereby facilitating the processing of the second aperture 221 or the third aperture 231 and reducing the difficulty of hole-opening the second mask plate 22 or the third mask plate 23, for which reference may be made to the second embodiment of the pixel layout structure to achieve a similar technical effect.

The present disclosure further provides a display panel, and the display panel includes the pixel layout structure provided in any of the above embodiments, and thus has the technical effects provided by the above pixel layout structure, which will not be repeated herein. Other structures of the display panel may be found in the related art and will not be repeated.

The above is only some embodiments of the present disclosure, and is not intended to limit the scope of the present disclosure. Any equivalent structure or equivalent process transformation made by using the contents of the specification and the accompanying drawings of the present disclosure, or applied directly or indirectly in other related technical fields, is included in the scope of the present disclosure in the same way.

What is claimed is:

1. A pixel layout structure, comprising:
a plurality of repeating units arranged in an array;
wherein an outer contour of each repeating unit is a rectangle; each repeating unit comprises four pixel units, and each pixel unit comprises a first sub-pixel, a second sub-pixel, and a third sub-pixel that are adjacent to each other; an outer contour of each pixel unit is a rectangle; a shape of each of the first sub-pixel, the second sub-pixel, and the third sub-pixel is a polygon;
the four first sub-pixels are arranged around a center of the repeating unit; an outer contour of the four first sub-pixels comprises a first edge, a second edge, a third edge, and a fourth edge, the first edge being disposed opposite to the third edge and the second edge being disposed opposite to the fourth edge;
wherein each of the first edge and the third edge is arranged with two corresponding second sub-pixels, and each of the second edge and the fourth edge is arranged with two corresponding third sub-pixels; or
each of the first edge, the second edge, the third edge, and the fourth edge is arranged with a corresponding second sub-pixel and a corresponding third sub-pixel.

2. The pixel layout structure according to claim 1, wherein each repeating unit has a first symmetry axis and a second symmetry axis; the four pixel units are a first pixel unit, a second pixel unit, a third pixel unit, and a fourth pixel unit; the first pixel unit and the second pixel unit are arranged symmetrically along the first symmetry axis, the third pixel unit and the fourth pixel unit are arranged symmetrically along the first symmetry axis, the first pixel unit and the third pixel unit are arranged symmetrically along the second symmetry axis, and the second pixel unit and the fourth pixel unit are arranged symmetrically along the second symmetry axis.

3. The pixel layout structure according to claim 1, wherein the four pixel units are a first pixel unit, a second pixel unit, a third pixel unit, and a fourth pixel unit; the second pixel unit is formed by rotating the first pixel unit 90 degrees clockwise around the center of the repeating unit, and the fourth pixel unit is formed by rotating the first pixel unit 180 degrees clockwise around the center of the repeating unit, and the third pixel unit is formed by rotating the first pixel unit 270 degrees clockwise around the center of the repeating unit.

4. The pixel layout structure according to claim 1, wherein the first sub-pixel has a rectangular shape, the second sub-pixel has a right-angle trapezoid shape, and the third sub-pixel has a right-angle trapezoid shape; or
the first sub-pixel has a right triangle shape, the second sub-pixel has a right triangle shape, and the third sub-pixel has a right triangle shape.

5. The pixel layout structure according to claim 4, wherein the second sub-pixel has a right-angle trapezoid shape, and the third sub-pixel has a right-angle trapezoid shape; an acute corner of each right-angled trapezoid is corner-cut; or
the second sub-pixel has a right triangle shape, and the third sub-pixel has a right triangle shape; at least one acute corner of each right triangle is corner-cut.

6. The pixel layout structure according to claim 1, wherein any two adjacent repeating units are arranged in an axisymmetric manner.

7. The pixel layout structure according to claim 1, wherein the area of the first sub-pixel is greater than the area of the second sub-pixel, and the area of the first sub-pixel is greater than the area of the third sub-pixel; and/or
a color of the first sub-pixel is one of red, green, and blue; a color of the second sub-pixel is a remaining one of red, green, and blue; and a color of the third sub-pixel is the other of red, green, and blue.

8. The pixel layout structure according to claim 1, wherein the four first sub-pixels of the repeating unit are arranged adjacent to each other and in a rectangular shape; and/or, for any two adjacent repeating units, which are a repeating unit A and a repeating unit B, a side of the repeating unit A faces and is adjacent to a side of the repeating unit B, and a sub-pixel on the side of the repeating unit A and a sub-pixel the side of the repeating unit B are in same colors and are arranged adjacent to each other.

9. A display panel, comprising a pixel layout structure; wherein the pixel layout structure comprises:
a plurality of repeating units arranged in an array;
wherein an outer contour of each repeating unit is a rectangle; each repeating unit comprises four pixel units, and each pixel unit comprises a first sub-pixel, a second sub-pixel, and a third sub-pixel that are adjacent to each other; an outer contour of each pixel unit is a rectangle; a shape of each of the first sub-pixel, the second sub-pixel, and the third sub-pixel is a polygon;
the four first sub-pixels are arranged around a center of the repeating unit; an outer contour of the four first sub-pixels comprises a first edge, a second edge, a third edge, and a fourth edge, the first edge being disposed opposite to the third edge and the second edge being disposed opposite to the fourth edge;
wherein each of the first edge and the third edge is arranged with two corresponding second sub-pixels, and each of the second edge and the fourth edge is arranged with two corresponding third sub-pixels; or
each of the first edge, the second edge, the third edge, and the fourth edge is arranged with a corresponding second sub-pixel and a corresponding third sub-pixel.

10. The display panel according to claim 9, wherein each repeating unit has a first symmetry axis and a second symmetry axis; the four pixel units are a first pixel unit, a second pixel unit, a third pixel unit, and a fourth pixel unit; the first pixel unit and the second pixel unit are arranged symmetrically along the first symmetry axis, the third pixel unit and the fourth pixel unit are arranged symmetrically along the first symmetry axis, the first pixel unit and the third pixel unit are arranged symmetrically along the second symmetry axis, and the second pixel unit and the fourth pixel unit are arranged symmetrically along the second symmetry axis.

11. The display panel according to claim 9, wherein the four pixel units are a first pixel unit, a second pixel unit, a third pixel unit, and a fourth pixel unit; the second pixel unit is formed by rotating the first pixel unit 90 degrees clockwise around the center of the repeating unit, and the fourth pixel unit is formed by rotating the first pixel unit 180 degrees clockwise around the center of the repeating unit, and the third pixel unit is formed by rotating the first pixel unit 270 degrees clockwise around the center of the repeating unit.

12. The display panel according to claim 9, wherein the first sub-pixel has a rectangular shape, the second sub-pixel has a right-angle trapezoid shape, and the third sub-pixel has a right-angle trapezoid shape; or
the first sub-pixel has a right triangle shape, the second sub-pixel has a right triangle shape, and the third sub-pixel has a right triangle shape.

13. The display panel according to claim 12, wherein the second sub-pixel has a right-angle trapezoid shape, and the third sub-pixel has a right-angle trapezoid shape; an acute corner of each right-angled trapezoid is corner-cut; or
the second sub-pixel has a right triangle shape, and the third sub-pixel has a right triangle shape; at least one acute corner of each right triangle is corner-cut.

14. The display panel according to claim 9, wherein any two adjacent repeating units are arranged in an axisymmetric manner.

15. The display panel according to claim 9, wherein the area of the first sub-pixel is greater than the area of the second sub-pixel, and the area of the first sub-pixel is greater than the area of the third sub-pixel; and/or
a color of the first sub-pixel is one of red, green, and blue; a color of the second sub-pixel is a remaining one of red, green, and blue; and a color of the third sub-pixel is the other of red, green, and blue.

16. The display panel according to claim 9, wherein the four first sub-pixels of the repeating unit are arranged adjacent to each other and in a rectangular shape; and/or, for any two adjacent repeating units, which are a repeating unit A and a repeating unit B, a side of the repeating unit A faces and is adjacent to a side of the repeating unit B, and a sub-pixel on the side of the repeating unit A and a sub-pixel the side of the repeating unit B are in same colors and are arranged adjacent to each other.

17. A mask plate assembly, configured to prepare a pixel layout structure; wherein the pixel layout structure comprises:
a plurality of repeating units arranged in an array;
wherein an outer contour of each repeating unit is a rectangle; each repeating unit comprises four pixel units, and each pixel unit comprises a first sub-pixel, a second sub-pixel, and a third sub-pixel that are adjacent to each other; an outer contour of each pixel unit is a rectangle; a shape of each of the first sub-pixel, the second sub-pixel, and the third sub-pixel is a polygon;
the four first sub-pixels are arranged around a center of the repeating unit; an outer contour of the four first sub-pixels comprises a first edge, a second edge, a third edge, and a fourth edge, the first edge being disposed opposite to the third edge and the second edge being disposed opposite to the fourth edge;
wherein each of the first edge and the third edge is arranged with two corresponding second sub-pixels, and each of the second edge and the fourth edge is arranged with two corresponding third sub-pixels; or
each of the first edge, the second edge, the third edge, and the fourth edge is arranged with a corresponding second sub-pixel and a corresponding third sub-pixel;
wherein the mask plate assembly comprises:
a first mask plate, configured to vaporize the first sub-pixel; wherein the first mask plate defines a plurality of first apertures, and the four first sub-pixels of the repeating unit share a corresponding first aperture;
a second mask plate, configured to vaporize the second sub-pixel; wherein the second mask plate defines a plurality of second apertures; for any two adjacent repeating units, the second sub-pixels that are adjacent to each other on the two adjacent repeating units share a corresponding second aperture; and
a third mask plate, configured to vaporize the third sub-pixel; wherein the third mask plate defines a plurality of third apertures; for any two adjacent repeating units, the third sub-pixels that are adjacent to each other on the two adjacent repeating units share a corresponding third aperture.

18. The mask plate assembly according to claim 17, wherein each repeating unit has a first symmetry axis and a second symmetry axis; the four pixel units are a first pixel unit, a second pixel unit, a third pixel unit, and a fourth pixel unit; the first pixel unit and the second pixel unit are arranged symmetrically along the first symmetry axis, the third pixel unit and the fourth pixel unit are arranged symmetrically along the first symmetry axis, the first pixel unit and the third pixel unit are arranged symmetrically along the second symmetry axis, and the second pixel unit and the fourth pixel unit are arranged symmetrically along the second symmetry axis.

19. The mask plate assembly according to claim 17, wherein the four pixel units are a first pixel unit, a second pixel unit, a third pixel unit, and a fourth pixel unit; the second pixel unit is formed by rotating the first pixel unit 90 degrees clockwise around the center of the repeating unit, and the fourth pixel unit is formed by rotating the first pixel unit 180 degrees clockwise around the center of the repeating unit, and the third pixel unit is formed by rotating the first pixel unit 270 degrees clockwise around the center of the repeating unit.

20. The mask plate assembly according to claim 17, wherein the four first sub-pixels of the repeating unit are arranged adjacent to each other and in a rectangular shape; and/or, for any two adjacent repeating units, which are a repeating unit A and a repeating unit B, a side of the repeating unit A faces and is adjacent to a side of the repeating unit B, and a sub-pixel on the side of the repeating unit A and a sub-pixel the side of the repeating unit B are in same colors and are arranged adjacent to each other.
